(19) United States
(12) Patent Application Publication
(10) Pub. No.: US 2025/0314700 A1
(43) Pub. Date: Oct. 9, 2025

(54) DEVICE AND METHOD FOR CALCULATING SINGLE-PARTICLE ELECTROCHEMICAL MODEL

(71) Applicant: Shanghai Makesens Energy Storage Technology Co., Ltd., Shanghai (CN)

(72) Inventors: Pei SONG, Shanghai (CN); Qiong WEI, Shanghai (CN); Danfei GU, Shanghai (CN); Pingchao HAO, Shanghai (CN); Peng DING, Shanghai (CN); Guopeng ZHOU, Shanghai (CN); Xiao YAN, Shanghai (CN); Enhai ZHAO, Shanghai (CN)

(73) Assignee: Shanghai Makesens Energy Storage Technology Co., Ltd., Shanghai (CN)

(21) Appl. No.: 18/851,083

(22) PCT Filed: Aug. 16, 2022
(86) PCT No.: PCT/CN2022/112835

§ 371 Date: May 26, 2025

(30) Foreign Application Priority Data
Apr. 11, 2022 (CN) 202210375273.9

(51) Int. Cl. G01R 31/367

(52) U.S. Cl. CPC G01R 31/367

(57) ABSTRACT

A device and a method for calculating a single-particle electrochemical model are provided. The device comprises electrochemical calculation modules, a communication module, and a data forwarding module. The electrochemical calculation modules calculate internal performance of batteries in an energy storage system based on battery data in the energy storage system, and output calculation results. The communication module is connected to the electrochemical calculation modules, and configured to transmit the battery data in the energy storage system to each of the electrochemical calculation modules and output the calculation results output by the electrochemical calculation modules. The data forwarding module is connected to the communication module, the energy storage system, and a cloud server, and configured to obtain the battery data from the energy storage system, forward the battery data to the communication module, and forward the calculation results. The method reduces battery analysis time and enables precise analysis of battery aging.

### FIELD OF THE INVENTION

The present disclosure relates to the technical field of energy storage, and in particular, to the technical field of devices for energy storage power stations.

### BACKGROUND OF THE INVENTION

With the commercialization and widespread use of energy storage stations, the need for accurate estimation of the remaining available capacity of battery packs, as well as predicting battery aging and lifespan, has increased. The existing methods, such as the equivalent circuit method and the ampere-hour integration method, have inherent errors when calculating the remaining available capacity of battery packs. These errors tend to accumulate over time, making it impossible to accurately predict the degree of battery aging.

By estimating the electrochemical state variables of lithium-ion batteries, particularly the concentration of Li+ ions on the surface of the negative electrode, which is related to battery aging, the degree of battery aging can be accurately determined, allowing for the optimization of charging current and extending the battery's lifespan. However, most existing electrochemical state variable estimations are run on large servers or standalone PCs using specialized physical modeling software for development and testing. When handling or calculating large amounts of battery data, there are often issues such as long calculation time.

### SUMMARY OF THE INVENTION

In view of the above-mentioned shortcomings, the present disclosure provides a device and a method for calculating a single-particle electrochemical model, which address the technical issue of effectively obtaining the internal performance of batteries in energy storage power station.

A first embodiment of the present disclosure provides a device for calculating a single-particle electrochemical model, comprising electrochemical calculation modules, a communication module, and a data forwarding module. The electrochemical calculation modules are configured to calculate internal performance of batteries in an energy storage system based on battery data in the energy storage system, and output calculation results. The communication module is connected to the electrochemical calculation modules, and configured to transmit the battery data in the energy storage system to each of the electrochemical calculation modules and output the calculation results output by the electrochemical calculation modules. The data forwarding module is connected to the communication module, the energy storage system, and a cloud server, and configured to obtain the battery data from the energy storage system, forward the battery data to the communication module, and forward the calculation results transmitted by the communication module to the cloud server.

In some examples of the present disclosure, each of the electrochemical calculation modules is configured with a single-particle electrochemical model algorithm.

In some examples of the present disclosure, the electrochemical calculation modules are configured in an FPGA programmable device, to calculate the internal performance of the batteries in the energy storage system in parallel based on the battery data in the energy storage system.

In some examples of the present disclosure, the communication module is configured in the FPGA programmable device, or is configured in an ARM chip connected to the FPGA programmable device.

In some examples of the present disclosure, the communication module is configured in the ARM chip, and the communication module communicates with the FPGA programmable device through an AHB.

In some examples of the present disclosure, each of the electrochemical calculation modules receives a start instruction from the energy storage system and requests the battery data corresponding to either a battery cluster or a single battery that requires internal performance calculation, from the energy storage system.

In some examples of the present disclosure, the start instruction is issued by the cloud server to the energy storage system, or the start instruction is generated by the energy storage system.

In some examples of the present disclosure, the device is embedded in the energy storage system, and acquires the battery data from an energy management system or a battery management system of the energy storage system through the data forwarding module.

A second embodiment of the present disclosure provides a method for calculating a single-particle electrochemical model, comprising: configuring electrochemical calculation modules to calculate internal performance of batteries in an energy storage system based on battery data in the energy storage system, and to output calculation results; configuring a communication module connected to the electrochemical calculation modules, to transmit the battery data in the energy storage system to each of the electrochemical calculation modules and output the calculation results output by the electrochemical calculation modules; and configuring a data forwarding module respectively connected to the communication module, the energy storage system, and a cloud server, to obtain the battery data from the energy storage system, forward the battery data to the communication module, and forward the calculation results transmitted by the communication module to the cloud server.

In some examples of the present disclosure, each of the electrochemical calculation modules is configured with a single-particle electrochemical model algorithm, and the electrochemical calculation modules are configured in an FPGA programmable device, to calculate the internal performance of the batteries in the energy storage system in parallel based on the battery data in the energy storage system.

As described above, the presently disclosed device and method have the following beneficial effects.
1. The presently disclosed method allows for the calculation of internal electrochemical states of batteries within a local energy storage power station system, reducing battery analysis time and enabling precise analysis of battery aging.
2. The single-particle electrochemical model algorithm is encapsulated as an independent IP core, running on a Field-Programmable Gate Array (FPGA) core. By leveraging the programmability and parallel computing advantages of the FPGA core, it allows for rapid processing of large amounts of battery data, significantly reducing data processing time and providing a solid data analysis foundation for the safe operation and effective control of the entire energy storage power station.
3. The presently disclosed device is embedded within the local energy storage system. By a data forwarding interface module, said device obtains battery data from an energy management system (EMS) or a battery management system (BMS), reducing the time required to acquire data and eliminating data acquisition traffic costs.
4. The uniquely designed data forwarding module ensures that the external communication protocol of the presently disclosed device only requires a one-time development effort. By simply modifying the communication protocol of the data forwarding module, the high-performance device can be embedded in various energy storage systems.

### BRIEF DESCRIPTION OF DRAWINGS

FIG. 1 is a schematic structural diagram of a device for calculating a single-particle electrochemical model according to an embodiment of the present disclosure.

FIG. 2 is a flowchart of a method for calculating a single-particle electrochemical model according to an embodiment of the present disclosure.

FIG. 3 is a flowchart of a calculation process of an electrochemical calculation module in the method for calculating the single-particle electrochemical model according to an embodiment of the present disclosure.

### DETAILED DESCRIPTION OF THE INVENTION

The embodiments of the present disclosure will be described below. Those skilled can easily understand disclosure advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

The present disclosure provides a device and a method for calculating a single-particle electrochemical model, which address the technical issue of effectively obtaining the internal performance of batteries in energy storage power station.

The principle and implementation of the presently disclosed device and method will be described in detail below, so that the skilled person in the field can understand them without creative labor.

### Embodiment 1

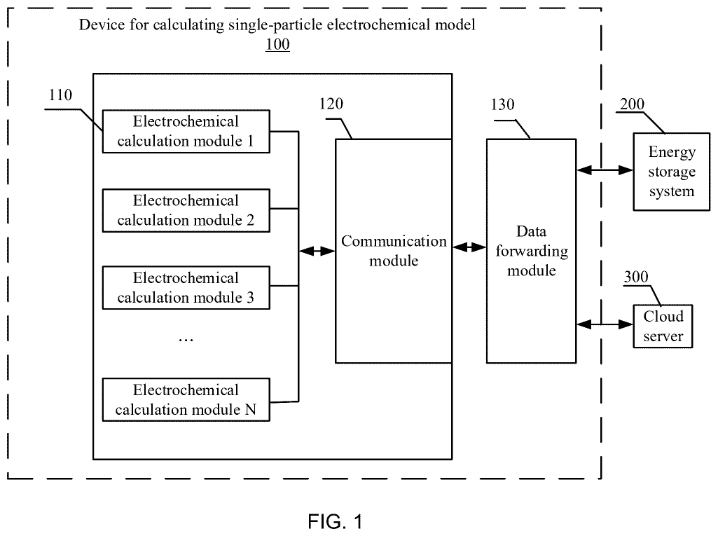

As shown in FIG. 1, Embodiment 1 provides a device 100 for calculating a single-particle electrochemical model, which comprises a plurality of electrochemical calculation modules 110, a communication module 120, and a data forwarding module 130.

The electrochemical calculation modules 110 are configured to calculate internal performance of batteries in an energy storage system 200 based on battery data in the energy storage system 200, and output calculation results.

Each of the electrochemical calculation modules 110 receives a start instruction from the energy storage system 200 and requests the battery data corresponding to either a battery cluster or a single battery that requires internal performance calculation, from the energy storage system 200.

The battery data comprises key data or preset data, such as real-time or historical charge/discharge voltage, current, and temperature.

The start instruction is issued by a cloud server 300 to the energy storage system 200, or the start instruction is generated by the energy storage system 200.

When the start instruction is issued by the cloud server 300, the start instruction may be transmitted to an energy management system (EMS) or a battery management system (BMS) of the energy storage system 200, and the EMS or BMS will then forward the start instruction to the electrochemical calculation modules 110; when the start instruction is generated by the EMS or BMS, a battery cluster or a single battery within the energy storage system 200 is designated for calculation, and the start instruction is transmitted to each of the electrochemical calculation modules 110 through the data forwarding module 130.

Upon receiving the start instruction, each of the electrochemical calculation modules 110 will proactively request relevant key data corresponding to batteries that require internal performance calculation, from the EMS or BMS. Once enough battery data have been collected, each of the electrochemical calculation modules 110 will begin the internal performance calculation.

As an example, each of the electrochemical calculation modules 110 is configured with a single-particle electrochemical model algorithm, or more specifically a single-particle lithium-ion electrochemical model algorithm. This algorithm is based on a single-particle lithium-ion battery model (SPM) and uses a single-particle approach to analyze solid diffusion and intercalation reaction kinetics in electrode particles. This algorithm calculates electrochemical parameters such as solid-phase potential, liquid-phase potential, exchange current density, solid-phase concentration, and liquid-phase concentration, which vary with changes in current and temperature. The results are compared with actual battery measurements to analyze changes in battery performance.

The electrochemical calculation modules 110 are configured in intellectual property (IP) cores of an FPGA programmable device, to calculate the internal performance of the batteries in the energy storage system 200 in parallel based on the battery data in the energy storage system 200. The IP cores refer to independent functional circuit modules within the FPGA programmable device.

In other words, each of the electrochemical calculation modules 110 encapsulates the FPGA-developed single-particle electrochemical model algorithm as an independent IP core, running on an FPGA core, which allows for accelerated parallel processing. The number of IP cores can be determined by the resources of the FPGA core.

For example, one IP core uses a portion of the FPGA core's total resources: 13% of Block RAM (BRAM), 18% of Digital Signal Processing (DSP), 8% of Flip-Flop (FF), and 18% of Look-Up Table (LUT), meaning that the FPGA core can support up to 5 IP cores running simultaneously.

The device 100 for calculating the single-particle electrochemical model encapsulates the single-particle lithium-ion electrochemical model algorithm as an independent IP core, running on the FPGA core. By leveraging the programmability and parallel computing advantages of the FPGA core, it allows for rapid processing of large amounts of battery data, significantly reducing data processing time and providing a solid data analysis foundation for the safe operation and effective control of the entire energy storage power station.

The communication module 120 is connected to the electrochemical calculation modules 110, and configured to transmit the battery data in the energy storage system 200 to each of the electrochemical calculation modules 110 and output the calculation results output by the electrochemical calculation modules 110.

Preferably, the communication module 120 is a Gigabit Ethernet-based communication module. This communication module 120 is essential for the proper operation of each of the electrochemical calculation modules 110, so as to input the necessary parameter variables for the single-particle electrochemical model algorithm calculations and to output the calculation results.

The communication module 120 is configured in the FPGA programmable device, or is configured in an Advanced RISC Machine (ARM) chip connected to the FPGA programmable device.

The communication module 120 is configured in the ARM chip, and the communication module 120 communicates with the FPGA programmable device through an Advanced High-Performance Bus (AHB).

That is, the communication module 120 may be implemented by the FPGA core or developed on an ARM architecture-based CPU, and then perform data interaction with the FPGA programmable device through the AHB.

The data forwarding module 130 is connected to the communication module 120, the energy storage system 200, and the cloud server 300, and configured to obtain the battery data from the energy storage system 200, forward the battery data to the communication module 120, and forward the calculation results transmitted by the communication module 120 to the cloud server 300 or to the EMS/BMS.

The device 100 for calculating the single-particle electrochemical model is embedded in the energy storage system 200, and acquires the battery data from the EMS or BMS of the energy storage system 200 through the data forwarding module 130.

By embedding the device 100 for calculating the single-particle electrochemical model within the energy storage system 200 and obtaining the battery data from the EMS or BMS, the device 100 for calculating the single-particle electrochemical model reduces the time required to acquire data and eliminates data acquisition traffic costs.

The data forwarding module 130 is independent of both the electrochemical calculation modules 110 and the communication module 120. The data forwarding module 130 enables data interaction with the electrochemical calculation modules 110, the EMS or BMS of the energy storage system 200, and the cloud server 300, facilitating data interaction between the device 100 for calculating the single-particle electrochemical model, the energy storage system 200, and the cloud server 300.

In other words, after each of the electrochemical calculation modules 110 completes its calculations, the communication module 120 forwards the calculation results to the EMS or BMS by the data forwarding module 130, or to the cloud server 300. Based on the calculation results, the EMS or BMS of the energy storage system 200 or the cloud server 300 can make corresponding control adjustments to the energy storage system 200.

The uniquely designed data forwarding module 130 ensures that the external communication protocol of the presently disclosed device 100 for calculating the single-particle electrochemical model only requires a one-time development effort. By simply modifying the communication protocol of the data forwarding module 130, the high-performance device 100 can be embedded in various energy storage systems 200.

Working processes of the presently disclosed device 100 for calculating the single-particle electrochemical model are as follows.

When the start instruction is issued by the cloud server 300, the start instruction may be transmitted to the EMS or BMS, and the EMS or BMS will then forward the start instruction to the electrochemical calculation modules 110; when the start instruction is generated by the EMS or BMS, a battery cluster or a single battery within the energy storage system 200 is designated for calculation, and the start instruction is transmitted to each of the electrochemical calculation modules 110 through the data forwarding module 130.

Upon receiving the start instruction, each of the electrochemical calculation modules 110 will proactively request relevant key data corresponding to batteries that require internal performance calculation, from the EMS or BMS. Once enough battery data has been collected, each of the electrochemical calculation modules 110 will begin the internal performance calculation.

In other words, after each of the electrochemical calculation modules 110 completes its calculations, the communication module 120 forwards the calculation results to the EMS or BMS by the data forwarding module 130, or to the cloud server 300. Based on the calculation results, the EMS or BMS of the energy storage system 200 or the cloud server 300 can make corresponding control adjustments to the energy storage system 200.

From the above, the presently disclosed device 100 for calculating the single-particle electrochemical model can be easily embedded in various lithium-ion battery energy storage systems and applied to a range of small and medium-sized lithium battery energy storage stations, which allows localized real-time precise analysis of individual cell data, enabling more accurate calculations and predictions of the State of Charge (SOC) and battery aging time of the batteries in the energy storage station from an electrochemical perspective.

### Embodiment 2

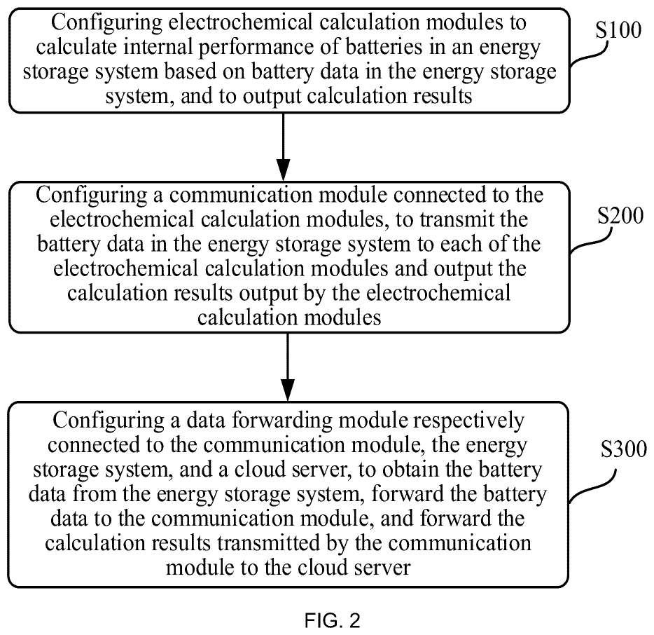

As shown in FIG. 2, the present disclosure further provides a method for calculating a single-particle electrochemical model, comprising steps S100-S300.

Step S100 comprises: configuring electrochemical calculation modules to calculate internal performance of batteries in an energy storage system based on battery data in the energy storage system, and to output calculation results.

Step S200 comprises: configuring a communication module connected to the electrochemical calculation modules, to transmit the battery data in the energy storage system to each of the electrochemical calculation modules and output the calculation results output by the electrochemical calculation modules.

Step S300 comprises: configuring a data forwarding module respectively connected to the communication module, the energy storage system, and a cloud server, to obtain the battery data from the energy storage system, forward the battery data to the communication module, and forward the calculation results transmitted by the communication module to the cloud server.

The above steps are described in detail below.

Step S100 comprises: configuring electrochemical calculation modules 110 to calculate internal performance of batteries in an energy storage system 200 based on battery data in the energy storage system 200, and to output calculation results.

Each of the electrochemical calculation modules 110 receives a start instruction from the energy storage system 200 and requests the battery data corresponding to either a battery cluster or a single battery that requires internal performance calculation, from the energy storage system 200.

The battery data comprises key data or preset data, such as real-time or historical charge/discharge voltage, current, and temperature.

The start instruction is issued by a cloud server 300 to the energy storage system 200, or the start instruction is generated by the energy storage system 200.

When the start instruction is issued by the cloud server 300, the start instruction may be transmitted to the EMS or BMS, and the EMS or BMS will then forward the start instruction to the electrochemical calculation modules 110; when the start instruction is generated by the EMS or BMS, a battery cluster or a single battery within the energy storage system 200 is designated for calculation, and the start instruction is transmitted to each of the electrochemical calculation modules 110 through the data forwarding module 130.

Upon receiving the start instruction, each of the electrochemical calculation modules 110 will proactively request relevant key data corresponding to batteries that require internal performance calculation, from the EMS or BMS. Once enough battery data has been collected, each of the electrochemical calculation modules 110 will begin the internal performance calculation.

As an example, each of the electrochemical calculation modules 110 is configured with a single-particle electrochemical model algorithm. Specifically, the single-particle electrochemical model algorithm is a single-particle lithium-ion electrochemical model algorithm.

The electrochemical calculation modules 110 are configured in IP cores of an FPGA programmable device, to calculate the internal performance of the batteries in the energy storage system 200 in parallel based on the battery data in the energy storage system 200. The IP cores refer to independently functional circuit modules within the FPGA programmable device.

In other words, each of the electrochemical calculation modules 110 encapsulates the FPGA-developed single-particle electrochemical model algorithm as an independent IP core, running on an FPGA core, which allows for accelerated parallel processing. The number of IP cores can be determined by the resources of the FPGA core.

The device 100 for calculating the single-particle electrochemical model encapsulates the single-particle lithium-ion electrochemical model algorithm as an independent IP core, running on the FPGA core. By leveraging the programmability and parallel computing advantages of the FPGA core, it allows for rapid processing of large amounts of battery data, significantly reducing data processing time and providing a solid data analysis foundation for the safe operation and effective control of the entire energy storage power station.

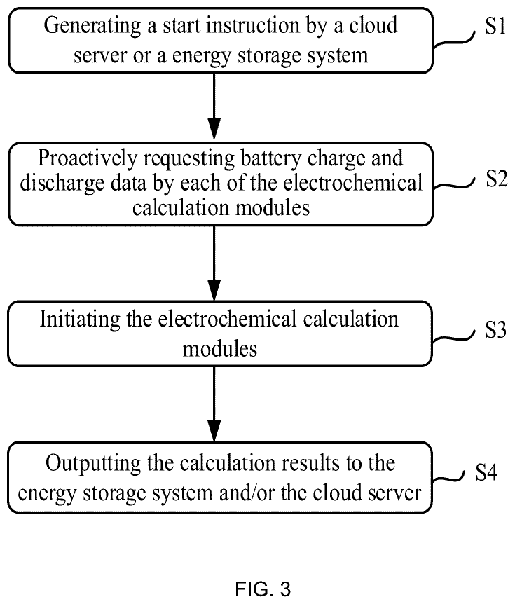

As shown in FIG. 3, the working processes of each of the electrochemical calculation modules 110 are as follows.

Step S1 comprises: generating the start instruction by the cloud server 300 or the energy storage system 200.

When the start instruction is issued by the cloud server 300, the start instruction may be transmitted to the EMS or BMS, and the EMS or BMS will then forward the start instruction to the electrochemical calculation modules 110; when the start instruction is generated by the EMS or BMS, a battery cluster or a single battery within the energy storage system 200 is designated for calculation, and the start instruction is transmitted to each of the electrochemical calculation modules 110 through the data forwarding module 130.

Step S2 comprises: proactively requesting battery charge and discharge data by each of the electrochemical calculation modules 110.

Upon receiving the start instruction, each of the electrochemical calculation modules 110 will proactively request relevant key data corresponding to batteries that require internal performance calculation, from the EMS or BMS.

Step S3 comprises: initiating the electrochemical calculation modules 110.

Once enough battery data has been collected, each of the electrochemical calculation modules 110 will begin the internal performance calculation.

Step S4 comprises: outputting the calculation results to the energy storage system 200 and/or the cloud server 300.

In other words, after each of the electrochemical calculation modules 110 completes its calculations, the communication module 120 forwards the calculation results to the EMS or BMS by the data forwarding module 130, or to the cloud server 300. Based on the calculation results, the EMS or BMS of the energy storage system 200 or the cloud server 300 can make corresponding control adjustments to the energy storage system 200.

Step S200 comprises: configuring a communication module 120 connected to the electrochemical calculation modules 110, to transmit the battery data in the energy storage system 200 to each of the electrochemical calculation modules 110 and output the calculation results output by the electrochemical calculation modules 110.

Preferably, the communication module 120 is a Gigabit Ethernet-based communication module. This communication module 120 is essential for the proper operation of each of the electrochemical calculation modules 110, so as to input the necessary parameter variables for the single-particle electrochemical model algorithm calculations and to output the calculation results.

The communication module 120 is configured in the FPGA programmable device, or is configured in an Advanced Reduced-Instruction-Set-Computer (RISC) Machine (ARM) chip connected to the FPGA programmable device.

The communication module 120 is configured in the ARM chip, and the communication module 120 communicates with the FPGA programmable device through an AHB.

That is, the communication module 120 may be implemented by the FPGA core or developed on an ARM architecture-based CPU, and then perform data interaction with the FPGA programmable device through the AHB.

Step S300 comprises: configuring a data forwarding module 130 respectively connected to the communication module 120, the energy storage system 200, and the cloud server 300, to obtain the battery data from the energy storage system 200, forward the battery data to the communication module 120, and forward the calculation results transmitted by the communication module 120 to the cloud server 300.

The data forwarding module 130 is connected to the communication module 120, the energy storage system 200, and the cloud server 300, and configured to obtain the battery data from the energy storage system 200, forward the battery data to the communication module 120, and forward the calculation results transmitted by the communication module 120 to the cloud server 300 or to the EMS/BMS.

The device 100 for calculating the single-particle electrochemical model is embedded in the energy storage system 200, and acquires the battery data from the EMS or BMS of the energy storage system 200 through the data forwarding module 130.

By embedding the device 100 for calculating the single-particle electrochemical model within the energy storage system 200 and obtaining the battery data from the EMS or BMS, the device 100 for calculating the single-particle electrochemical model reduces the time required to acquire data and eliminates data acquisition traffic costs.

The data forwarding module 130 is independent of both the electrochemical calculation modules 110 and the communication module 120. The data forwarding module 130 enables data interaction with the electrochemical calculation modules 110, the EMS or BMS of the energy storage system 200, and the cloud server 300, facilitating data interaction between the device 100 for calculating the single-particle electrochemical model, the energy storage system 200, and the cloud server 300.

In other words, after each of the electrochemical calculation modules 110 completes its calculations, the communication module 120 forwards the calculation results to the EMS or BMS by the data forwarding module 130, or to the cloud server 300. Based on the calculation results, the EMS or BMS of the energy storage system 200 or the cloud server 300 can make corresponding control adjustments to the energy storage system 200.

The uniquely designed data forwarding module 130 ensures that the external communication protocol of the presently disclosed device 100 for calculating the single-particle electrochemical model only requires a one-time development effort. By simply modifying the communication protocol of the data forwarding module 130, the high-performance device 100 for calculating the single-particle electrochemical model can be embedded in various energy storage systems 200.

The presently disclosed method allows for the calculation of internal electrochemical states of batteries within a local energy storage power station system, reducing battery analysis time and enabling precise analysis of battery aging. The single-particle electrochemical model algorithm is encapsulated as an independent IP core, running on an FPGA core. By leveraging the programmability and parallel computing advantages of the FPGA core, it allows for rapid processing of large amounts of battery data, significantly reducing data processing time and providing a solid data analysis foundation for the safe operation and effective control of the entire energy storage power station. The presently disclosed device is embedded within the local energy storage system. By a data forwarding interface module, said device obtains battery data from the EMS or BMS, reducing the time required to acquire data and eliminating data acquisition traffic costs. The uniquely designed data forwarding module ensures that the external communication protocol of the presently disclosed device only requires a one-time development effort. By simply modifying the communication protocol of the data forwarding module, the high-performance device can be embedded in various energy storage systems. Therefore, the present disclosure effectively overcomes various shortcomings in the existing technology and has high industrial utilization value.

The above-mentioned embodiments are for exemplarily describing the principle and effects of the present disclosure instead of limiting the present disclosure. Those skilled in the art can make modifications or changes to the above-mentioned embodiments without going against the spirit and the range of the present disclosure. Therefore, all equivalent modifications or changes made by those skilled in the art without departing from the spirit and scope of the disclosure will be covered by the appended claims.

1. A device for calculating a single-particle electrochemical model, comprising:
electrochemical calculation modules, configured to calculate internal performance of batteries in an energy storage system based on battery data in the energy storage system, and output calculation results;
a communication module, connected to the electrochemical calculation modules, and configured to transmit the battery data in the energy storage system to each of the electrochemical calculation modules and output the calculation results output by the electrochemical calculation modules; and
a data forwarding module, connected to the communication module, the energy storage system, and a cloud server, and configured to obtain the battery data from the energy storage system, forward the battery data to the communication module, and forward the calculation results transmitted by the communication module to the cloud server.

2. The device according to claim 1, wherein each of the electrochemical calculation modules is configured with a single-particle electrochemical model algorithm.

3. The device according to claim 1, wherein the electrochemical calculation modules are configured in an FPGA programmable device, to calculate the internal performance of the batteries in the energy storage system in parallel based on the battery data in the energy storage system.

4. The device according to claim 3, wherein the communication module is configured in the FPGA programmable device, or is configured in an ARM chip connected to the FPGA programmable device.

5. The device according to claim 4, wherein the communication module is configured in the ARM chip, and the communication module communicates with the FPGA programmable device through an AHB.

6. The device according to claim 1, wherein each of the electrochemical calculation modules receives a start instruction from the energy storage system and requests the battery data corresponding to either a battery cluster or a single battery that requires internal performance calculation, from the energy storage system.

7. The device according to claim 6, wherein the start instruction is issued by the cloud server to the energy storage system, or the start instruction is generated by the energy storage system.

8. The device according to claim 1, wherein the device is embedded in the energy storage system, and acquires the battery data from an energy management system or a battery management system of the energy storage system through the data forwarding module.

9. A method for calculating a single-particle electrochemical model, comprising:
configuring electrochemical calculation modules to calculate internal performance of batteries in an energy storage system based on battery data in the energy storage system, and to output calculation results;
configuring a communication module connected to the electrochemical calculation modules, to transmit the battery data in the energy storage system to each of the electrochemical calculation modules and output the calculation results output by the electrochemical calculation modules; and
configuring a data forwarding module respectively connected to the communication module, the energy storage system, and a cloud server, to obtain the battery data from the energy storage system, forward the battery data to the communication module, and forward the calculation results transmitted by the communication module to the cloud server.

10. The method according to claim 9, wherein each of the electrochemical calculation modules is configured with a single-particle electrochemical model algorithm, and the electrochemical calculation modules are configured in an FPGA programmable device, to calculate the internal performance of the batteries in the energy storage system in parallel based on the battery data in the energy storage system.
